(19) United States
(12) Patent Application Publication
(10) Pub. No.: US 2003/0152700 A1
(43) Pub. Date: Aug. 14, 2003

(54) Process for synthesizing uniform nanocrystalline films

(75) Inventors: Jes Asmussen, Okemos, MI (US); Wen Shin Huang, East Lansing, MI (US)

Correspondence Address: MCLEOD & MOYNE, P.C., 2190 COMMONS PARKWAY, OKEMOS, MI, 48864, US

(73) Assignee: Board of Trustees operating Michigan State University, East Lansing, MI

(21) Appl. No.: 10/073,710

(22) Filed: Feb. 11, 2002

(51) Int. Cl. C23C 16/26

(52) U.S. Cl. 427/249.8; 427/569

(57) ABSTRACT

A CVD process for producing nanocrystalline films using a plasma (56, 312) created by an argon atmosphere (at least about 90 percent by volume) containing methane (preferably about at least about 1% by volume) and optionally hydrogen (preferably 0.001 to 2% by volume) is described. Strictly controlled gas purity and an apparatus which excludes oxygen and nitrogen from being introduced from outside of the chamber (40, 305) are used. The films are coated on various substrates to provide seals, optical applications such as on lenses and as a substrate material for surface acoustic wave (SAW) devices.

### GOVERNMENT RIGHTS

This invention was supported by National Science Foundation Grant No. DMR-98-09688. The Government has certain rights to this invention.

### CROSS-REFERENCE TO RELATED APPLICATIONS

None.

### BACKGROUND OF THE INVENTION

### FIELD OF THE INVENTION

The present invention relates to a process for the production of uniform nanocrystalline diamond films on a substrate. In particular, the present invention relates to the use of conditions which exclude nitrogen and oxygen from a reactor chamber where a plasma is generated to synthesize the film uniformly. The plasma generating gas contains more than ninety percent (90%) by volume argon along with ten percent (10%) or less methane and optionally hydrogen. The films are particularly useful for optical applications such as lenses; seals; and surface acoustic wave (SAW) devices.

### DESCRIPTION OF RELATED ART

The present invention is an improvement upon the deposition processes developed by Gruen et al. See for example U.S. Pat. Nos. 5,989,511; 5,849,079 and 5,772,760. The patents to Gruen et al describe processes for synthesizing smooth nanocrystalline diamond films starting with the mixing of carbonaceous vapors such as methane or acetylene gas with a gas stream consisting of mostly an inert or noble gas, such as argon, with, if necessary, also small fractional (1-3%) additions of hydrogen gas. This gas is then activated in, for example, a plasma environment, and under the appropriate conditions of pressure, gas flow, microwave power, substrate temperature and reactor configuration nanocrystalline diamond films are deposited on a substrate.

The process described in the above referenced patents produce nanocrystalline films that are deposited over a very limited substrate area (about two inch (5.08 cm) substrate diameters) and that are synthesized over a pressure range (55-150 Torr) deposition window. The limited small area deposition areas are associated with the microwave deposition technology and processes described in the Gruen et al patents.

Other related patents are U.S. Pat. Nos. 5,209,916 to Gruen; 5,328,676 to Gruen; 5,370,855 to Gruen; 5,462,776 to Gruen; 5,620,512 to Gruen; 5,571,577 to Zhang et al; 5,645,645 to Zhang et al; 5,897,924 to Ulczynski et al and 5,902,640 to Krauss.

### OBJECTS

Therefore, an object of the invention is to provide a process that deposits smooth, uniform, nanocrystalline diamond films preferably over large (greater than two inch (5.08 cm) diameters and as large as eight to ten inch (20.32 to 25.4 cm) diameters) substrate areas. An additional object of this invention is to provide a process that uniformly synthesizes smooth nanocrystalline diamond films over a large pressure range of 50 Torr to over 300 Torr. These and other objects will become increasingly apparent by reference to the following description and the drawings.

### SUMMARY OF THE INVENTION

A CVD process for producing nanocrystalline films using a plasma created by an argon atmosphere (at least about 90 percent by volume) containing methane (preferably about at least about 1% by volume) and optionally hydrogen (preferably 0.001 to 2% by volume) is described. Strictly controlled gas purity and an apparatus which excludes oxygen and nitrogen from being introduced from outside of the chamber are used. The films are coated on various substrates to provide seals, optical applications such as on lenses and as a substrate material for surface acoustic wave (SAW) devices.

The present invention relates to a process for depositing a nanocrystalline diamond film with a grain size between 1 and 100 nm on a surface of a substrate, which comprises:

(a) providing a plasma generating apparatus for depositing the diamond film on the substrate from the plasma including a plasma source employing a radiofrequency, including UHF or microwave, wave coupler means which is metallic and in the shape of a hollow cavity and which is excited in a TM mode of resonance and optionally including a static magnetic field around the plasma which aids in coupling radiofrequency energy at electron cyclotron resonance and aids in confining ions in the plasma in an electrically insulated chamber means in the coupler means, and wherein the chamber means has a central longitudinal axis in common with the coupler means and is mounted in closely spaced and sealed relationship to an area of the coupler means with an opening from the chamber means at one end; gas supply means for providing a gas which is ionized to form the plasma in the chamber means, wherein the radiofrequency wave applied to the coupler means creates and maintains the plasma around the central longitudinal axis in the chamber means; movable metal plate means in the cavity mounted in the coupler means perpendicular to the central longitudinal axis and movable along the central longitudinal axis towards and away from the chamber means; and a movable probe means connected to and extending inside the coupler means for coupling the radiofrequency waves to the coupler means;

(b) providing the substrate, wherein the surface to be placed in the plasma has been roughened and cleaned; and

(c) providing the substrate in the insulated chamber on a substrate holder adjacent to the plasma generated in the chamber, wherein the gas in the chamber is at a pressure between 50 and 300 Torr in the presence of the radiofrequency waves for generating the plasma, wherein the gas is ninety percent by volume or more of argon along with methane and optionally hydrogen and essentially without oxygen or nitrogen and the chamber is essentially free from leaks of nitrogen or oxygen or mixtures thereof into the chamber, so as to generate the plasma and to deposit the nanocrystalline diamond film on the substrate.

Preferably the probe means is elongate and is mounted in the coupler means along the central longitudinal axis of the chamber means and coupler means with an end of the probe means in spaced relationship to the chamber means. A stage means is in the opening of the chamber and forms part of the cavity and provides for mounting of the substrate on the substrate holder. The stage means has a support surface which is preferably in a plane around the longitudinal axis and can optionally be moved towards and away from the plasma in the chamber means so that the substrate can be coated with the diamond film from the plasma.

The microwave is preferably at 2.45 GHz or at 915 MHz. Preferably the gas contains about 1% methane. Preferably the mode of the plasma is selected from the group consisting of TM012 and TM013.

Preferably the stage means is allowed to thermally float at a temperature between about 575° C. and 900° C. (top side of substrate) at a pressure up to about 250 Torr. The term “thermally floating” means that there is no externally applied heating or cooling of the substrate. The substrate is allowed to have the temperature varied by changing the pressure in the chamber. In order to maintain a temperature of the substrate at 575° to 900° C., at pressures above about 250 Torr to 300 Torr, external cooling can be used to control substrate temperature. Preferably the pressure of the gas is controlled between about 60 and 240 Torr and input gas flow rates varying between about 50 and 600 sccm.

Diamond particles are preferably used for roughening the surface of the substrate by abrasion. These diamond particles preferably have a grain size between about 0.1 to 0.3 micrometers (micron), however, the diamond grains can be as large as several microns in size. Other substrate surface roughening means can be used, such as plasma etching or bias enhanced seeding.

The insulated chamber is vacuum evacuated over time so that preferably there is less than about 10 ppm of combined oxygen and nitrogen or oxygen or nitrogen molecules in the chamber when providing the gas which generates the plasma in the chamber. The chamber is made as leak-free as possible to prevent oxygen or nitrogen from entering the chamber.

The substrate can be silica glass, silicon carbide or silicon or various ceramic materials. The nanocrystalline diamond film preferably has a thickness of at least about 20 to 50 nanometers. Preferably the substrate is silicon or a silica glass and the substrate holder is molybdenum. The substrate on which the diamond is deposited preferably has a surface area greater than about 20 cm and preferably between 20 cm² and up to 320 cm².

The present invention thus provides a new method of synthesizing smooth, nanocrystalline diamond films. Building upon the experimental results of Gruen et al (J. Appl. Phys. 84 1981 (1998)), microwave plasma assisted film deposition was performed using hydrogen poor, carbon containing Ar plasma chemistries. Experiments are performed with a MSU (Michigan State University, East Lansing, Mich.) developed microwave plasma reactor (Kuo, K. P., et al., Diamond Relat. Mater. 6 1907 (1992)). It is desired to grow films uniformly over two inch (5.08 cm) diameter, preferably 3 to 4 inch diameter (7.62-10.2 cm), substrates and to minimize the grain size. Plasma reactor outputs, i.e., film uniformity, growth rate, film quality and roughness were investigated in the following Examples vs. pressure, input gas chemistry, gas purity, total gas flow rates, and reactor geometry. The variation of plasma reactor outputs were examined to understand the deposition process.

### BRIEF DESCRIPTION OF DRAWINGS

FIGS. 1 to 1D are sectional views of one prior art embodiment of reactor 10. FIG. 1E is a generalized view of the reactor of FIGS. 1 to 1D. FIG. 1F is a front cross-sectional view of a specific reactor 300 used in the Examples. FIG. 1G is a schematic view showing the vacuum system 400 for the reactor 300 of FIG. 1F.

FIG. 2 is a graph showing UV Raman results at various concentrations of hydrogen (H₂).

FIG. 3 is a graph showing UV Raman results at various hydrogen concentrations on a broader scale, of angstrom units.

FIGS. 4A to 4H are AFM micrographs of the diamond coated surfaces at various pressures with no hydrogen.

FIGS. 5A to 5H are AFM micrographs of the diamond coated surfaces at various pressures with 4 parts hydrogen.

FIGS. 6A to 6G are AFM micrographs of the diamond coated surfaces at a pressure of 120 Torr while varying the hydrogen concentration.

FIGS. 7A to 7F are AFM micrographs of diamond coated surfaces produced at 120 Torr for nitrogen impurity investigation.

FIGS. 8 and 8A are graphs showing growth rate, FIG. 8, and roughness, FIG. 8A, as a function of pressure with no hydrogen.

FIGS. 9 and 9A are graphs of growth rate (FIG. 9) and roughness (FIG. 9A) as a function of pressure with 4 parts hydrogen.

FIGS. 10 and 10A are graphs showing growth rate, (FIG. 10) and roughness (FIG. 10A) at a pressure of 120 Torr, as a function of hydrogen concentration.

FIGS. 11 and 11A are graphs showing growth rate, FIG. 11, and roughness, FIG. 11A, at a pressure of 120 Torr with nitrogen as an impurity.

FIG. 12 is a TEM diamond film image (characterized at Argon National Laboratories) of a diamond film prepared by the present inventors, where the bright spots are grains of diamond aligned in the diffraction direction <111>.

FIG. 13 is a histogram of the diamond particle distribution for the diamond specimen of FIG. 12.

FIG. 14 is a graph showing the plasma emission spectrum intensity versus wavelength for determining Tᵣₒₜ.

FIG. 15 is a graph of Tᵣₒₜ versus pressure.

FIG. 16 is a graph of Tᵣₒₜ as a function of hydrogen flow.

FIG. 17 is a graph showing infrared transmission of nanocrystalline diamond coated on silicon wafer.

FIG. 18 is a perspective view of a nanocrystalline diamond coated silicon carbide seal 300.

FIG. 19 is a perspective view of a substrate holder 451 used to enable a coating of a seal 450.

FIGS. 20 and 20A are graphs showing surface profile as a function of position on the seal 450.

### DESCRIPTION OF PREFERRED EMBODIMENTS

In particular, the invention describes a preferred process that can uniformly deposit nanocrystalline films over relatively large diameter substrates and over a 80-250 Torr deposition pressure regime. The increased deposition pressure has the benefit of allowing increased deposition rates. While the deposition process described in the Examples is demonstrated using a seven inch (17.78 cm), 2.45 GHz microwave plasma reactor operating with a five inch maximum diameter discharge zone, the process and methods can be readily scaled up to a 13 inch (33.02 cm) diameter discharge zone and a 20 inch (50.80 cm) 915 MHz microwave reactor.

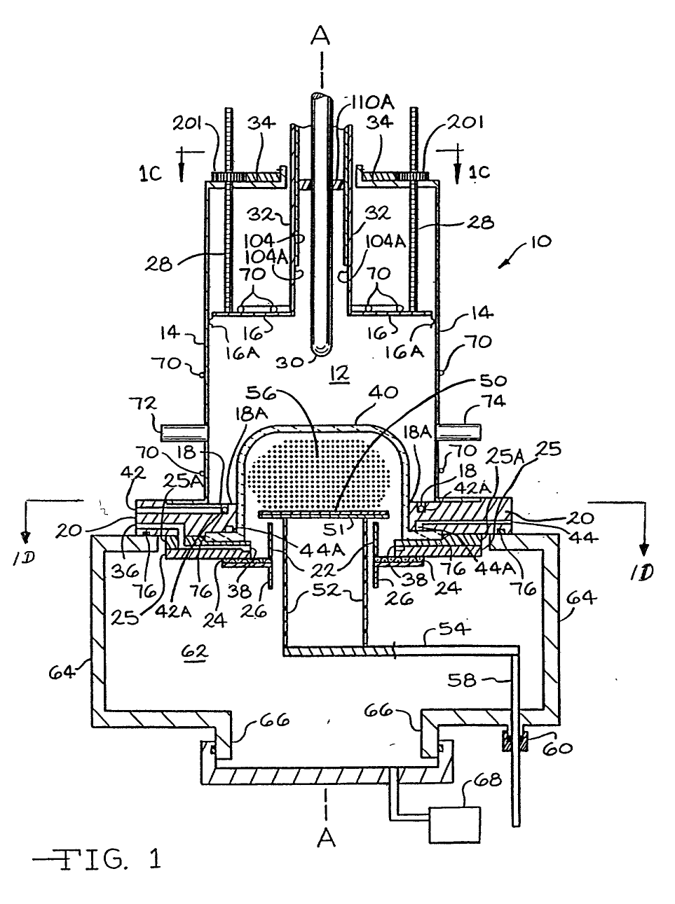

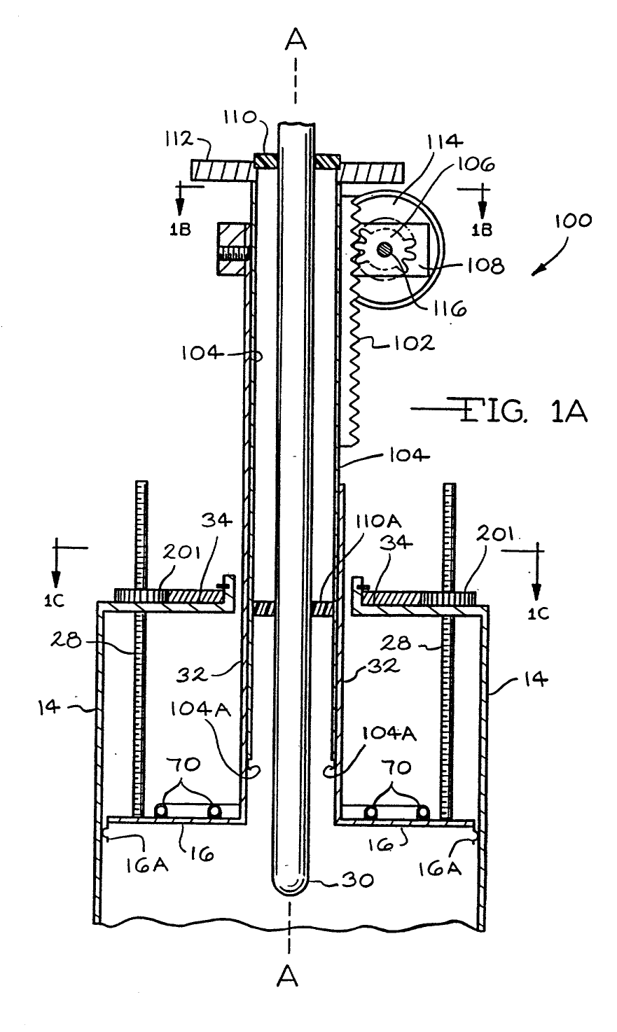

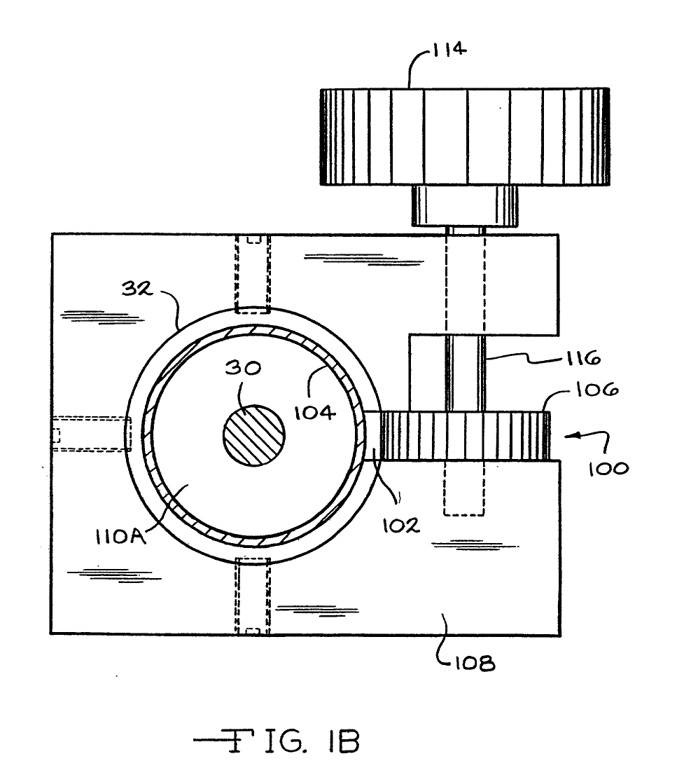

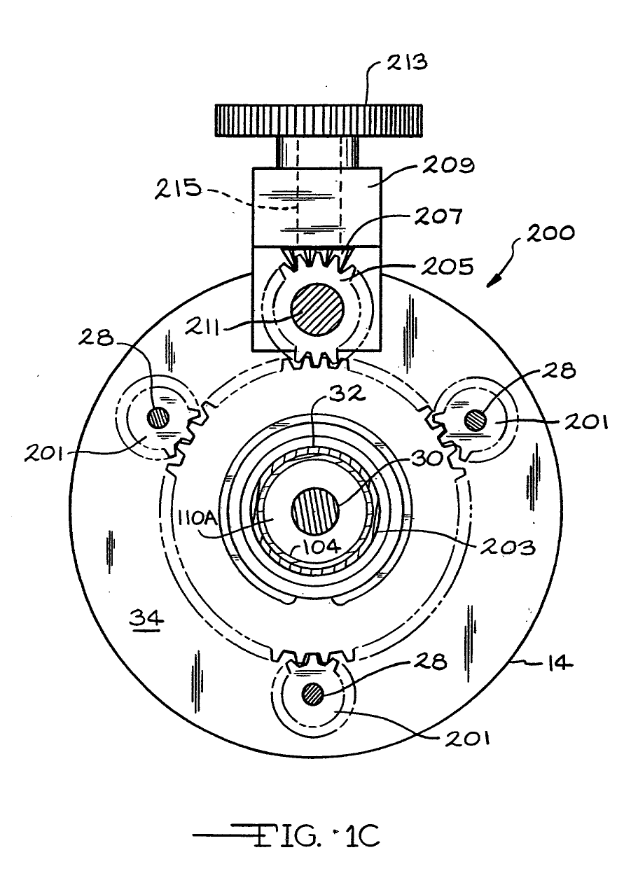

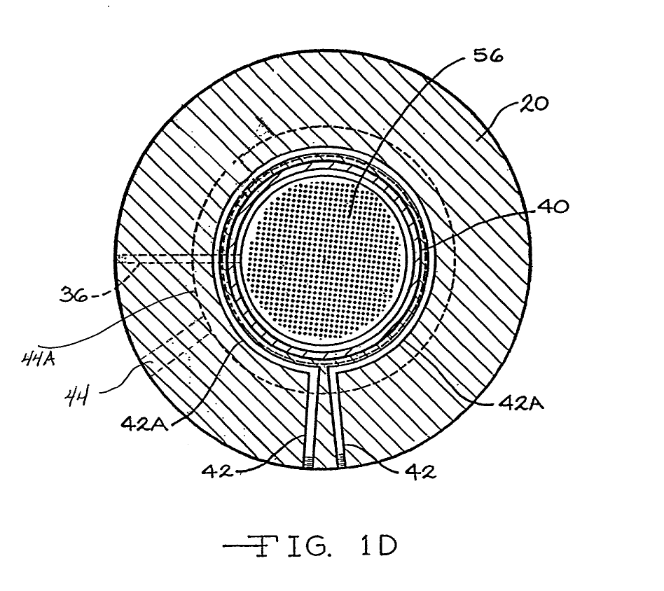

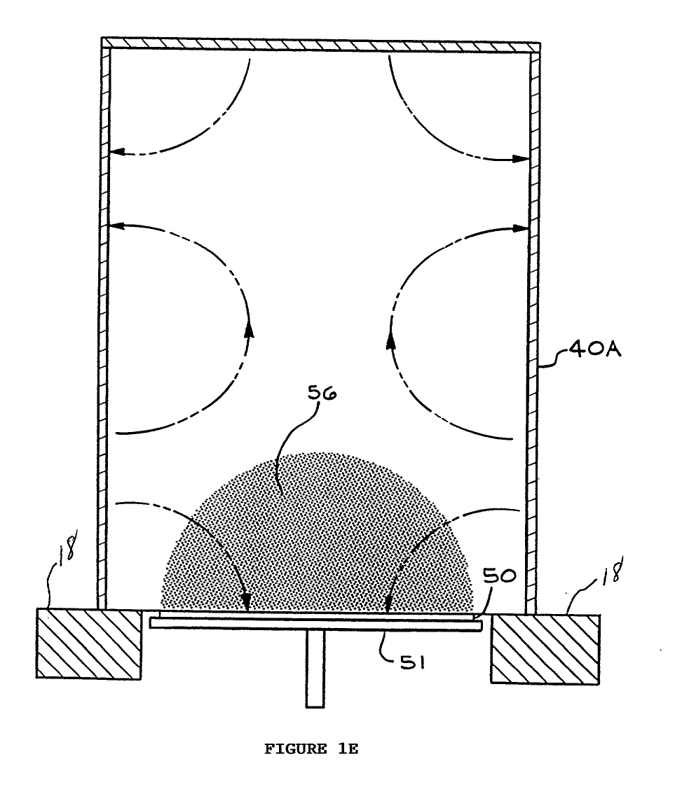

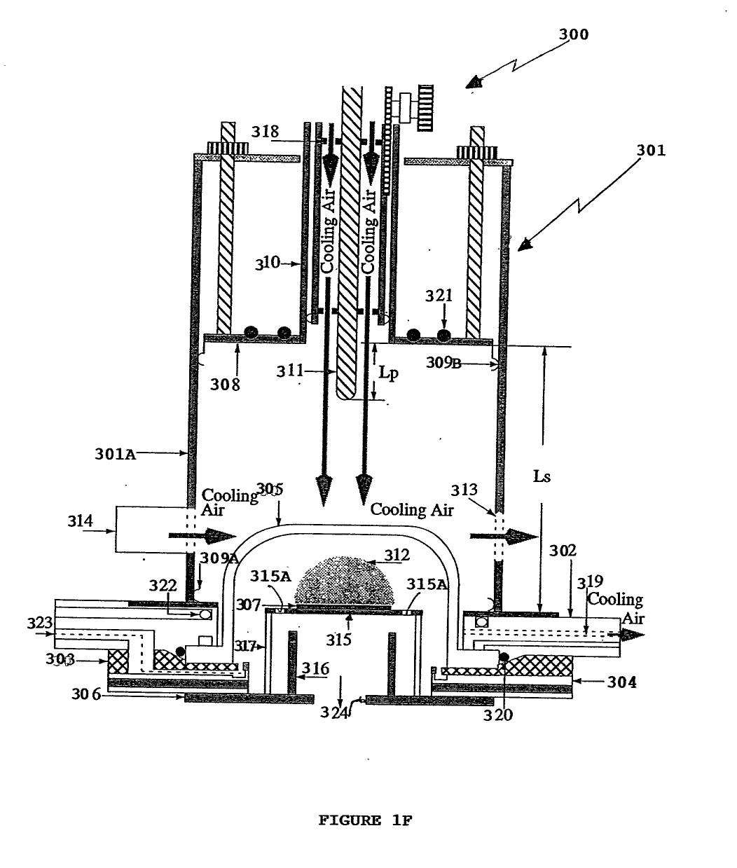

The basic description of the preferred microwave plasma deposition apparatus employed in the present invention is set forth in U.S. Pat. No. 5,311,103, by Asmussen et al which is incorporated by reference. Cross-sectional views of an apparatus 10 are shown in FIGS. 1 to 1D. This type of apparatus has been built in a variety of sizes ranging in diameter from four inches (10.16 cm) to over twenty inches (50.80 cm). The corresponding discharge sizes range from two to over thirteen inches (5 to 33 cm). This technology has been extensively tested and evaluated using conventional methane/hydrogen gas inputs.

The present invention operates in a mostly argon gas environment. In this inert gas environment microwave discharges readily arc, constrict and filamentize, and thus do not produce the large uniform discharges that are required for a uniform, controlled deposition process.

Discharge constriction in the process of the present invention was eliminated and the plasma control was established (1) by appropriate applicator and substrate holder design, (2) by controlling the start-up process and input gas mixture, (3) by adjusting the reactor energy removal process, (4) by operating the substrate in a “thermally floating condition” at less than 250 Torr, and (5) particularly by operating with a leak free vacuum system and ultra pure input gases. Process control of the purity of the input gases and a leak from vacuum environment produces small crystal sizes and uniform films. The details of the preferred reactor design, the system, the deposition methodology, the deposited nanocrystalline film properties, and the variation of the film deposition process versus the experimental input parameter space are presented in the Examples and FIG. 1F.

The basic applicator design has been described in earlier patents. Besides the above mentioned U.S. Pat. No. 5,311,103, other pertinent patents are U.S. Pat. Nos. 4,585,668; 4,792,772 and 4,727,293. These microwave reactors were designed to excite only one mode and thus arc formation and filamentation is controlled and minimized. The electromagnetic field patterns are controlled to create and sustain the discharge in the proper position. The discharge is then only produced in the desired position; i.e. just above but in contact with the substrate. When in operation the plasma essentially attaches itself to the substrate and thus does not float away and attach itself to the walls of the deposition chamber.

The substrate holder was designed to operate in the thermally floating condition. That is, the heating and cooling is provided by the plasma itself. The holder used is a circular molybdenum plate that was placed on a quartz tube adjacent to a stage at the cavity applicator bottom plate as shown in FIG. 1F. Using this design, the substrate holder is said to be operating in the thermally floating condition. Substrates that were to be coated are placed on the molybdenum holder. Deposition uniformity was controlled by adjusting the height of the holder up or down, and at each operating pressure by adjusting the input power so that the plasma discharge covers the substrate in a manner required for uniform deposition.

FIGS. 1 to 1E show one embodiment of a plasma coating reactor apparatus 10 of the present invention. The basic components of the apparatus 10 are displayed in the longitudinal cross-sectional view of FIG. 1. The cavity applicator 12 has a 178 millimeter inside diameter and is an open ended metallic cylinder 14. A sliding short 16, which is electrically connected to the side walls via the finger stocks 16A, forms the top end of the cavity applicator 12. The lower section of the cavity applicator 12 consists of the cavity bottom surface 18, having a metallic step 18A, the metal base-plate 20, a metal tube 22 supported on a metal screen 24 which is mounted on the underside of a bottom plate 25 supported from the base-plate 20 by intermediate ring plate 25A. The sliding short 16 can be moved up and down along the longitudinal axis A-A of the cavity applicator 12 by the moving threaded rods 28 with a gear assembly 100 (FIGS. 1A and 1B), which provides an adjusting means for the probe 30. The excitation probe 30 is supported in an inner sleeve 104 by insulators 110 and 110A. The inner sleeve 104 provides a holder means for the probe 30 and is in turn adjustably mounted inside of a short sleeve 32. The short sleeve 32 along with the sliding short 16 are independently adjustable with respect to the metallic cylinder 14 through a mechanical gear assembly 200 as an adjustable means (FIG. 1C) mounted on plate 34 with threaded rods 28 mounted through the gears 201 of the gear assembly 200. This short sleeve 32 along with the gear assembly 200 provide a support means for the probe 30. The inner sleeve 104 has fingers 104A that contact the short sleeve 32 and the inner sleeve 104 moves longitudinally along axis A-A to adjust the distance between the probe 30 and a quartz dome chamber 40. Cap 112 (FIG. 1A) provides for mounting the insulator 110 on inner sleeve 104. Cap 112 is also the connector to the input coaxial cable. A knob 114 is secured to pinion gear 106 by shaft 116, which is rotatably mounted on housing 108.

The adjustable sliding short 16 and excitation probe 30 provide the impedance tuning mechanism to minimize the reflected power in the cavity applicator 12. The source gas, which is supplied through the source gas inlet 36 (FIG. 1D) and annular source gas ring 38, is confined at the lower section of the cavity 12 by the quartz dome chamber 40. The base-plate 20 and quartz dome chamber 40 are cooled by the water cooling channel 42 and gas cooling channel 44 through the annular water cooling rings 42A and gas cooling rings 44A.

The substrate 50 to be coated lays on top of a susceptor on substrate holder 51, which is supported by a non-metallic tube 52. The non-metallic tube 52 stands on an optionally movable stage 54 which is used to change the position of the substrate 50 with respect to the plasma 56. The stage 54 is connected to a movable rod 58 which passes through a vacuum seal 60. The metal tube 22 ensures that the plasma 56 stays on top of the substrate 50 by breaking the resonance near the metal screen 24. The metal choke sleeve 26 provides a floating end of the cavity applicator 12 and a choke of the radiofrequency radiation. This design minimizes the plasma volume by creating a plasma 56 adjacent to the substrate 50. The cylindrical symmetry of the sliding short 16 and probe 30 and apparatus 10 configuration ensures that the plasma 56 generated has an inherent cylindrical symmetry. The apparatus 10 is mounted on a vacuum chamber 62 with chamber walls 64 and a usual chamber conduit 66 leading to a vacuum pump 68.

FIG. 1B shows the details of the gear assembly 100 for moving the probe 30 and the inner sleeve 104 independent of the sliding short 16 and short sleeve 32. The gear assembly 100 includes a linear rack 102 mounted on the inner sleeve 104 and a pinion gear 106 mounted on a housing 108 secured to the short sleeve 32.

FIG. 1C shows the threaded rods 28 mounted on gears 201 of the mechanical gear assembly 200. The gears 201 are turned by gear 203 around the short sleeve 32 by bevel gears 205 and 207 rotatably mounted on housing 209. Gear 205 is mounted on pin 211 secured to housing 209. A second knob 213 attached to shaft 215 is journaled in housing 209 and turns the gear 207 and thus the gears 205, 203 and 201 in succession to move the sliding short 16 along the axis A-A. The basic mechanism is described in U.S. Pat. No. 4,792,772.

FIG. 1D shows a cross-sectional view of plasma 56 inside quartz dome chamber 40 and water cooling rings 42A in base plate 20. Source gas inlet 36 (dotted lines) provides the gas for the plasma 56. The gas cooling rings 44A are below the water cooling rings 42A. The gas cooling line 44 is shown in dotted lines.

Water cooling lines 70 are provided in the sliding short 16 and around the metallic cylinder 14. Air cooling passages 72 and 74 are provided to cool the cavity 12.

Vacuum seals 76 are provided to insure that the quartz dome chamber 40 with plasma 56 is sealed from the outside atmosphere.

As shown in FIG. 1E, the preferred form of the improved coating reactor apparatus 10 limits the extent of the microwaves in the chamber 40 to a plane adjacent the bottom surface 18 of the cavity 12, adjacent to step 18A. This serves to retain the plasma 56 in the upper part of chamber 40A as shown. That way, the plasma 56 density is uniform across the surface area of the substrate 50, which ensures uniform treatment of the substrate 50 surface.

FIG. 1F shows a cross-sectional drawing of a modified microwave cavity plasma reactor apparatus 300 configuration which was used in the following Examples. As shown, the side wall 301A of the applicator 301 is made of a 17.78 cm inside diameter cylindrical brass tube. This brass tube, which forms the conducting shell of the applicator 301, is electrically shorted to a water-cooled baseplate assembly 302 by finger stock 309A and by a sliding short 308 via a finger stock 309B. Thus the cylindrical volume bounded by the sliding short 308, the applicator 301 side wall 301A and the baseplate 302 forms the cylindrical electromagnetic excitation region. With a fixed excitation frequency and cavity radius, the cavity length is adjusted to excite the TM₀₁₃ mode as determined by J. Zhang et al (Experimental Development of Microwave Cavity Plasma Reactors for Large Area and High Rate Diamond Film Deposition, J. Zhang, Ph.D. Thesis, Michigan State University, East Lansing, Mich. (1993)) and excites a hemispherical plasma discharge 312 in good contact with the substrate 307. In the operating condition, the coaxial excitation probe 311 is removed far enough from the discharge to eliminate the near excitation field effect caused by the probe 311. 2.45 GHz (CW) microwave power is coupled into the cylindrical cavity applicator 301 through the probe 311 which is inside a coaxial waveguide 310 which is located in the center of the sliding short 308. The sliding short 308 controls the application height, Lₛ and the excitation probe controls the depth of the coaxial excitation probe, Lₚ. Both Lₛ and Lₚ can be moved up and down along the longitudinal axis of the applicator 301 cavity side wall 301A and can be adjusted independently to excite the desired electromagnetic mode and optimally match the resonance. The applicator height Lₛ and probe depth are adjusted approximately to 21.7 cm to 3.2 cm, respectively (Zhang, Experimental Development of Microwave Cavity Plasma Reactors for Large Area and High Rate Diamond Film Deposition, J. Zhang, Ph.D. Thesis, Michigan State University, East Lansing, Mich. (1993)). The baseplate assembly consists of a water-cooling tube 322 and air-cooled tube 319 in baseplate assembly 302, an annular input gas feed plate 303, and a gas distribution plate 304. A 12.5 cm inside diameter quartz dome 305 is sealed by O-ring 320 in contact with baseplate assembly 302. The thermally floating substrate holder 315 assembly includes a flow pattern regulator 315A, a metal tube 316, a quartz tube 317, and a holder-baseplate 306. The premixed input gases are fed into the gas inlet 323 in the baseplate assembly. The substrate 307 is placed on top of a substrate holder 315, also called a flow pattern regulator, which is supported by a quartz tube 317. Quartz tubes of different heights, preferably 47 to 52 cm, can be used to change the position of the substrate 307 with respect to the plasma 312 to optimize the film deposition. The metal tube 316 which serves as an electromagnetic field resonance breaker is placed inside the quartz tube 317. The metal tube 316 prevents the plasma discharge from forming underneath the substrate 307 by reducing the electric field underneath the substrate 307. The metal tube 316 and quartz tube 317 are placed on a holder-baseplate 306 which has 3 cm diameter hole at its center to pass the hot gases from within the quartz dome 305 to the exhaust roughing pump 402 (see FIG. 1G). The holder baseplate 306, the annular input gas feed plate 303, and the gas distribution plate 304 introduce a uniform ring of input gases into the quartz dome 305 where the electromagnetic fields produce the microwave discharge or plasma. The plasma consists of a mixture of neutral gases, electrons, and ions, i.e. dissociated species. A screened view window 313 is cut into the cavity all for viewing the discharge 312. By focusing an optical pyrometer onto the substrate through the view window 313, the substrate 307 temperature can be determined. An air blower with 60 CFM (cubic foot per minute) blows the cooling air stream into the air blower inlet 314, onto the quartz dome 305 and cavity side wall 301A, and then finally flows out of the cavity through the air blower outlet 313 and optical access ports 319 in the baseplate assembly 302. An air blower existing inside the microwave power supply (not shown) adds another air cooling stream into the microwave cavity plasma reactor apparatus 300. Two Teflon pieces 318 were drilled with four of ⅛″ diameter through holes. This allows the cooling air from the air blower in the microwave power supply to flow through the coaxial waveguide (see arrows), onto quartz dome 305 and cavity side walls 301A, and then flows out of the air blower outlet 319 and the screen view window 313. Two fans (not shown) are used to cool the cavity applicator side wall 301A. The air cooling provided by the fans also extends the lifetime of the quartz dome 305.

The microwave cavity plasma reactor 300 is mounted on a process chamber with the chamber outlet leading to vacuum pumps. On an improved system, water cooling tubes 321 and 322 were replaced by a chiller which controls the temperature of the input coolant liquid. The chiller coolant temperature can be set by the system operator. The chiller allows for repetitive operation of the disposition system even as the external room temperature is changed.

The thermally floating substrate holder 315 setup utilizes a gas flow pattern regulator. The substrate holder 315 is a flat plate with a series of holes 315A arranged in a circle right inside the circumference. The gas flow coming out the gas inlet 323, into the quartz dome 305, is directed by the holes 315A as it flows through the plasma discharge 312. The configuration is designed to increase the uniformity of the film deposition by changing the flow pattern in the plasma discharge and influencing the shape of the plasma discharge (Zhang, Experimental Development of Microwave Cavity Plasma Reactors for Large Area and High Rate Diamond Film Deposition, J. Zhang, Ph.D. Thesis, Michigan State University, East Lansing, Mich. (1993)).

### EXAMPLES

Experimental Procedure

1. Seeding Procedures

Without wafer pre-treatment, CVD nanocrystalline diamond films could not be synthesized during 8-hour experimental runs. Therefore, a nucleation enhancement step was required for the deposition of CVD nanocrystalline diamond from gas phase onto non-diamond substrates, like mirror-polished silicon. A scratched seeding procedure was utilized. The procedure for mechanical scratch seeding was as follows:

Place the substrate on the seeding stage.

Connect the seeding stage to a pump and turn on the power. The vacuum sucks the substrate and keeps the substrate from moving.

Sprinkle some quantity of AMPLEX™ (Worcester, Mass.) 0.1 μm sized natural diamond powder onto the surface of the substrate. If the humidity in the room is high, bake the diamond powder at 150° C. for 2 hours before usage.

Use a wrapped in a KIM WIPE™ (Kimberly-Clark, Roswell, Ga.) finger to polish the substrate with the combination of several different angles of straight line motion and several different diameters of circular motion. Make sure the substrate surface is scratched everywhere with a median force.

Put a piece of curved glass inside a container. Pick up the substrate from the seeding stage and put it in the container, on top of the curved glass, with the scratched surface facing down.

Fill the container with methanol to a liquid line above the substrate of about 1 cm.

Put the container in an ultrasonic bath for 30 minutes for cleaning and agitation purpose.

Take the substrate out and put it in another container with the scratched surface facing up. Filled the container with some acetone enough to cover the substrate.

Use Q-tip gently wipe the substrate surface to remove any dirt or diamond powder.

Put the substrate on a wafer holder.

Rinse the substrate with acetone and methanol for 2 minutes each step.

Rinse the substrate with de-ionized water for 15 minutes.

Blow dry with a clean room nitrogen gun.

Check the substrate surface cleanness under optical microscopy.

If there is dirt or diamond powder left on the substrate surface, repeat step 8 to step 14.

2. Start-up Procedure

FIG. 1G shows the vacuum pumping system 400. After loading the sample into the reactor 300, the system 400 is pumped down to less than 1-10 mTorr range using the mechanical roughing pump 402. Close roughing valve 401 and open the turbo isolation valve 403. Turn on the turbo molecular pump 404. Let the reactor apparatus 300 pump for a few hours until the base pressure is about 12˜10⁻⁶ Torr. When the reactor apparatus 300 reaches high vacuum status, turn off the turbo molecular pump 404 and close the turbo isolation valve 403. Now, the experiment run was initiated by the following steps.

Turn on the water to microwave power supply.

Turn on the microwave power supply. The power level control knob should be zero.

Turn the nitrogen purge to the pump.

Turn on the NESLAB™ (Neslab Instruments, Inc., Newington, N.H.) chiller and set the temperature at 15° C.

Set the experimental running time, input microwave power, pressure, and gas flows for each channel in the plasma software.

Set the experimental pressure on the pressure controller of the throttle valve.

Adjust the cavity length to 21.7 cm by moving the sliding short position and set the probe depth at Lp=3.2 cm (FIG. 1F).

When the turbo pump 404 is fully stopped, open a process valve 405 and turn on the mass flow controllers to let the input gases come in before opening the roughing valve 401 to prevent the impurity and pump oil in the line from being sucked in. (Optional, flushing the chamber with Argon gas. So far, there is no quantitative evidence that it changes the nanocrystalline diamond deposition result.)

Open the roughing valve 401. Now the chamber 305 pressure is controlled by an automatic throttle valve 406.

Enable the microwave power supply when the chamber 305 pressure reaches 10 Torr.

Turn on the cooling fans.

Slowly increase the input microwave power as pressure increases so that the hemispherical plasma discharge 312 covers the entire substrate surface.

Fine tune the cavity length, Ls and Lp (FIG. 1F) to obtain the minimum reflected power.

The experiment starts to run on its own under time control when the system pressure reaches the valued set in the pressure controller.

3. Shut-down Procedure

When the experiment is completed, the system will perform the shut down procedure as follows:

Turn off microwave power.

Turn off all the mass flow controllers.

The automatic throttle valve 406 to the roughing pump will close at 10 torr below set point. If there is a leak in the system and the atmospheric air is forced into the system, the throttle will reopen at the set point pressure to let the system pressure remain at the set point, below atmosphere.

### Example 1

4. Experimental Objectives

To develop a MPA CVD deposition process/methodology that enables nanocrystalline diamond films to be uniformly deposited over larger areas (3-10 inch diameter; 7.62-25.4 cm).

To investigate nanocrystalline quality and deposition uniformity vs. reactor geometry, substrate geometry, variable input gas chemistries, pressure, and total gas flow rates.

To investigate the influence of variable nitrogen concentrations (5-2500 ppm) on film growth rates, film uniformity, film quality (as measured by Raman), and film roughness.

To utilize a microwave plasma reactor 300 concept that is scalable to large areas, i.e., initiate experiments with a 2.45 GHz excited, 5 inch (12.70 cm) discharge with deposition on 3 inch (6.12 cm) substrates, then scale the discharges up to a 12 inch (30.48 cm) with a 915 MHz excitation. Film depositions can occur up to 10 inch (25.4 cm) diameter substrates.

Referring to FIG. 1F,

(1) Substrate holder 315 can be cooled, heated, or operated in a thermally floating condition.

(2) A three inch silicon substrate 307 was placed on an 11 cm diameter molybdenum substrate holder 315.

(3) A 4 inch (10.16 cm) hemispherical discharge 312 was created over and is in good contact with the substrate 307.

(4) 1-240 Torr pressures and 2.45 GHz, 1-4 kW microwaves were used.

(5) Top side and back side substrate 307 temperatures were measured via pyrometry.

5. Reactor Impurity Control

Input gases of ultra-high purity were used to minimize the introduction of impurities, such as nitrogen, oxygen, etc., into the system.

Purity of gases used were: Argon 99.999%, Hydrogen 99.9995%, Methane 99.99%, Hydrogen/Nitrogen mix 99.9995%.

Ultra-low leak rate of 4 mTorr/hr ensured negligible introduction of nitrogen from the atmosphere.

Combined impurities from the input gases raised the nitrogen impurity level to 5 ppm.

Levels of 10 ppm nitrogen in the gas phase are detectable in emission spectra.

Nitrogen was introduced for an impurity investigation using a pre-mixed gas which allowed exact control of the nitrogen in the gas phase.

6. Experimental Parameters

Three 3″ <100>Si substrates were used, mechanically scratched by 0.1 μm natural diamond powder.

The substrate holder 315 was operated in thermal floating condition.

The input power was 1000-2500W.

The substrate 307 temperatures were back side: 500-750° C. and top side: about 575°-900° C. (575° C. is the lower limit of the pyrometer used).

The pressure was 60-240 Torr

The Ar concentration was 90-99%; H₂ concentration: 0-9%;

CH₄ concentration: 1%.

The total gas flow rate was 100-600 sccm.

The N₂ impurity was 5-2500 ppm.

7. Deposition Uniformity Study

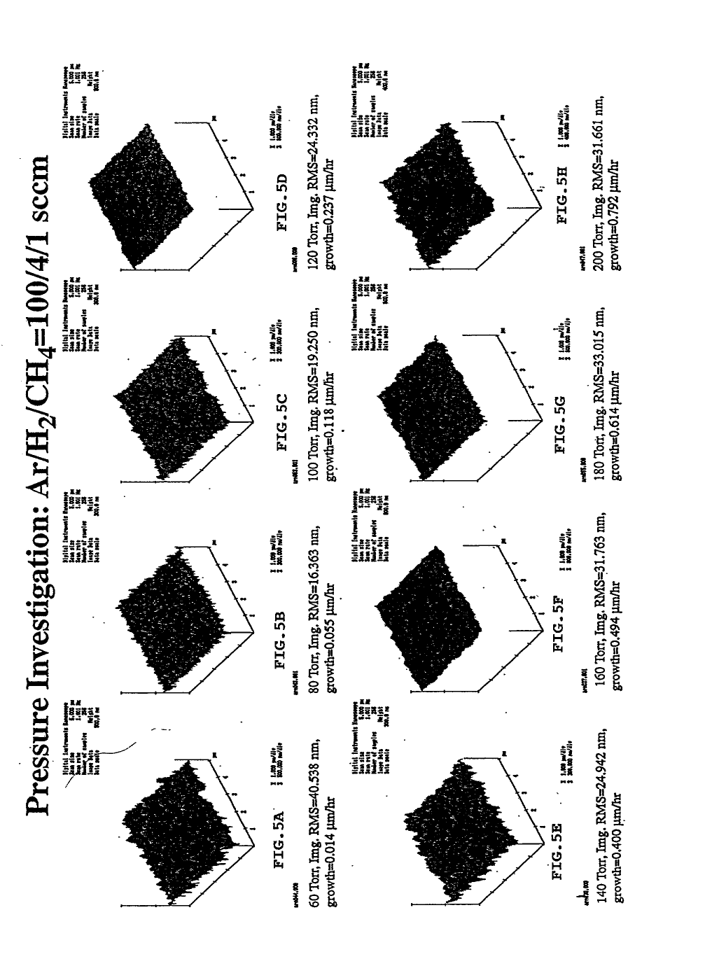

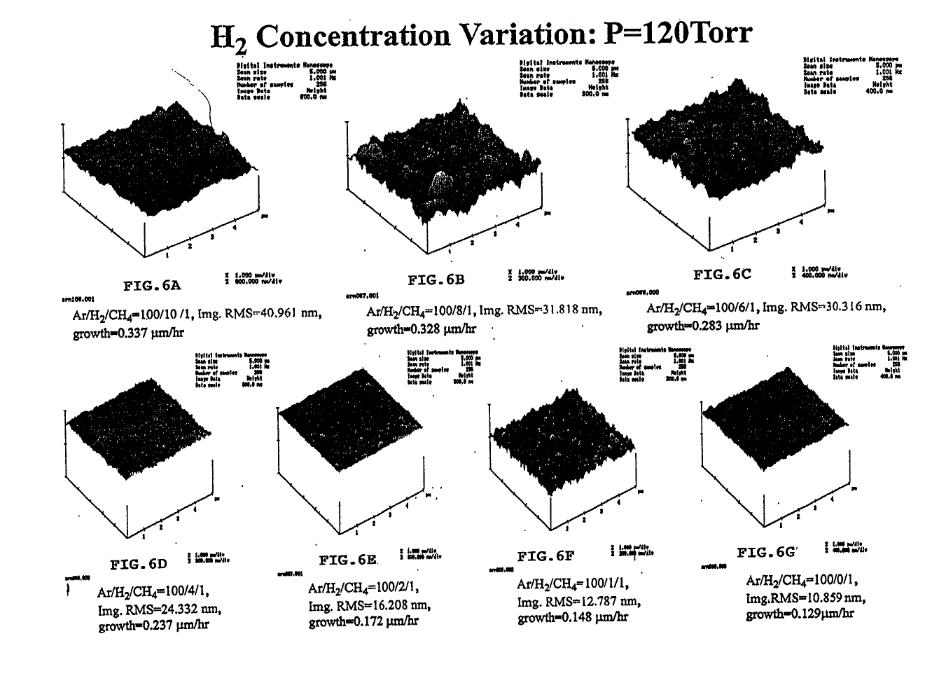

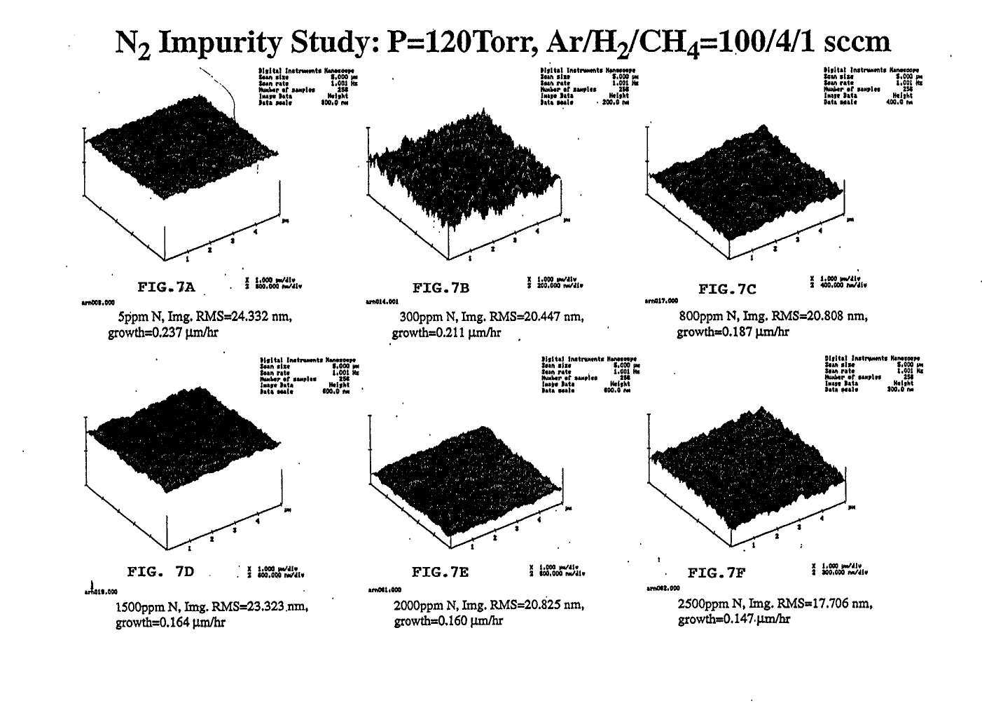

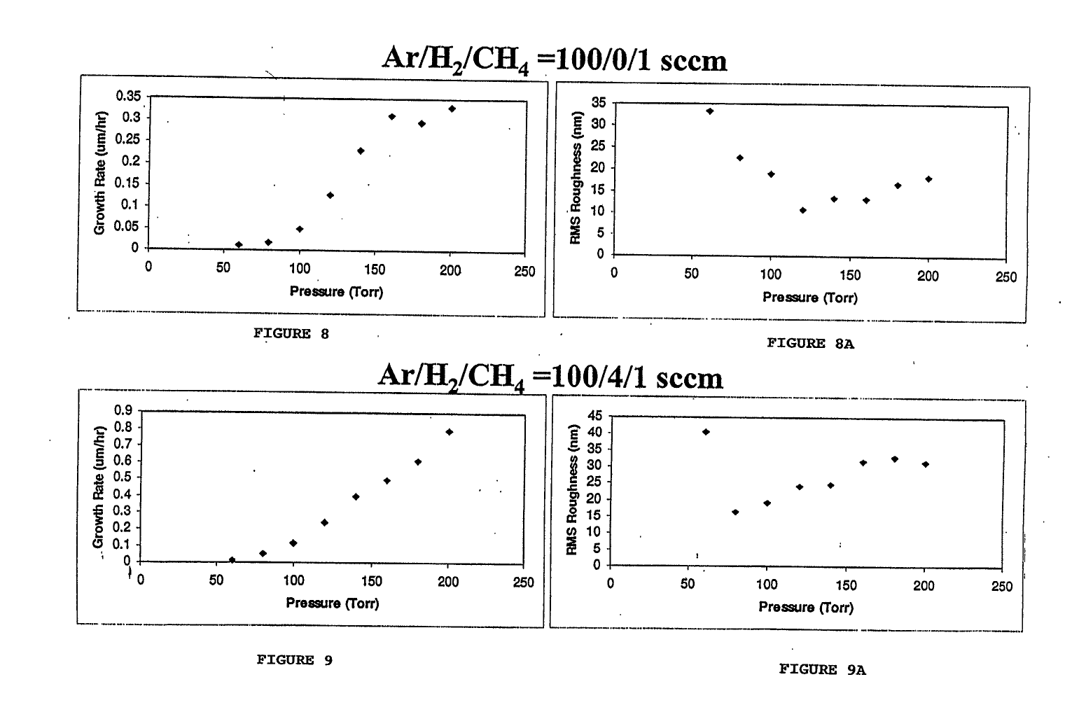

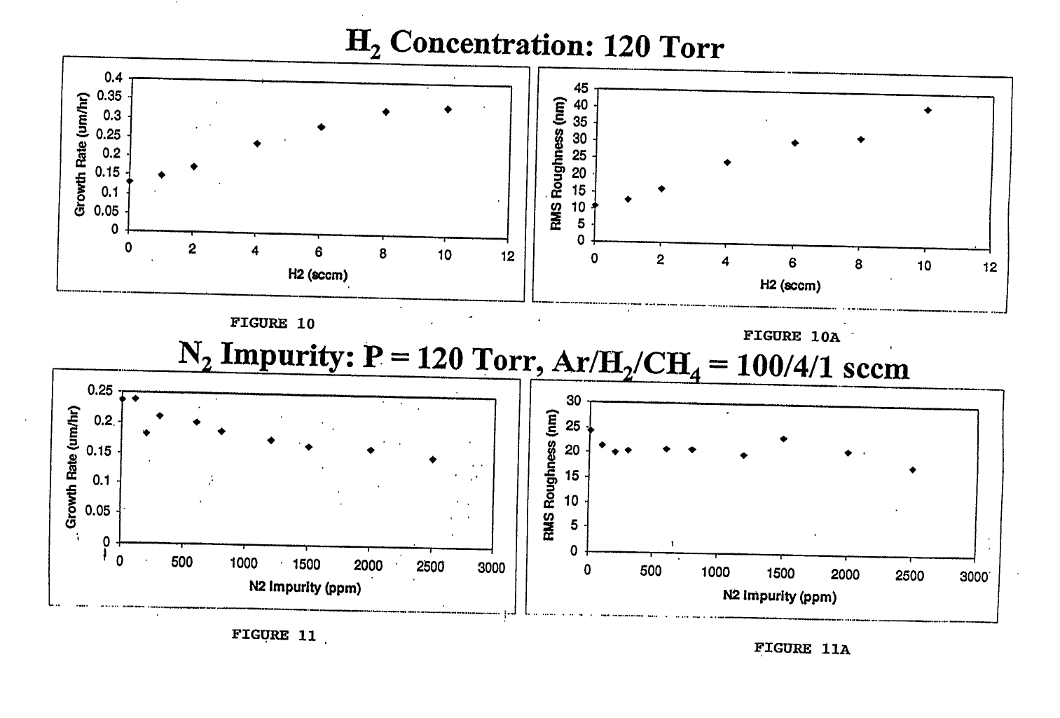

A series of experiments were performed as shown in FIGS. 2 to 19 to observe deposition uniformity over 3″ (7.62 cm) substrates.

In FIG. 2 1. by varying the H₂ concentrations, the variations of the height of graphitic peaks around 1580 cm⁻¹ have been observed. 2. Lower H₂ concentrations tend to have higher graphitic peaks. This usually indicates slightly more graphite content in the nanocrystalline diamond films.

In FIG. 3: By increasing the H₂ concentrations, the decreasing of the height of graphitic/amorphous carbon peaks around 1560 cm⁻¹ has been observed.

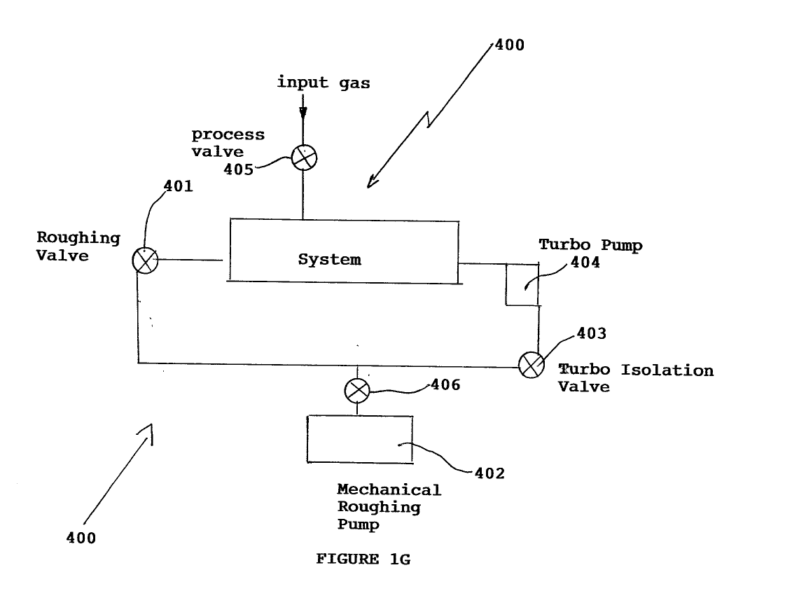

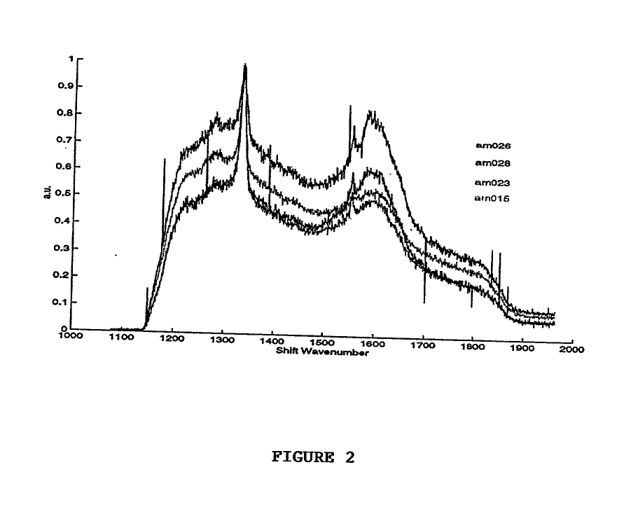

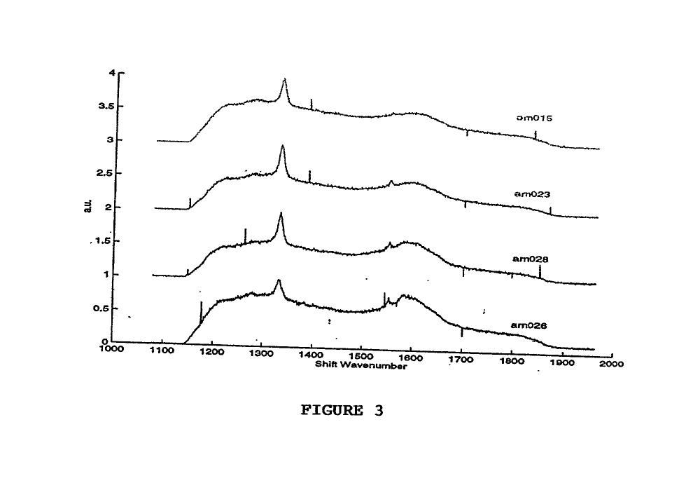

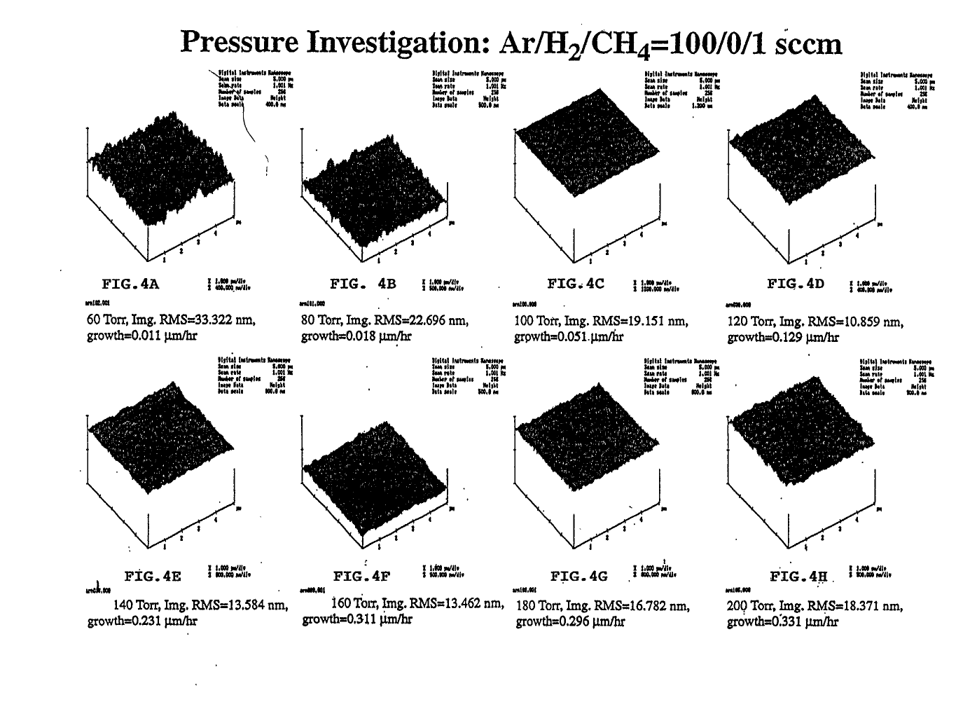

FIGS. 4 to 11 show the results of various experiments as indicated.

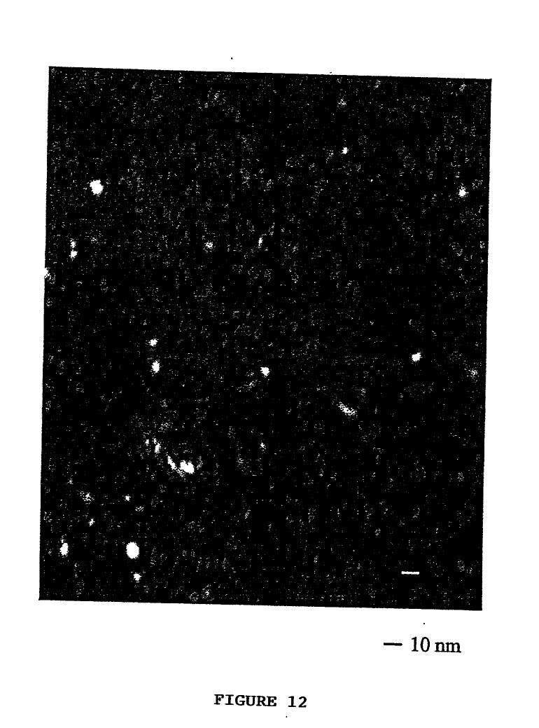

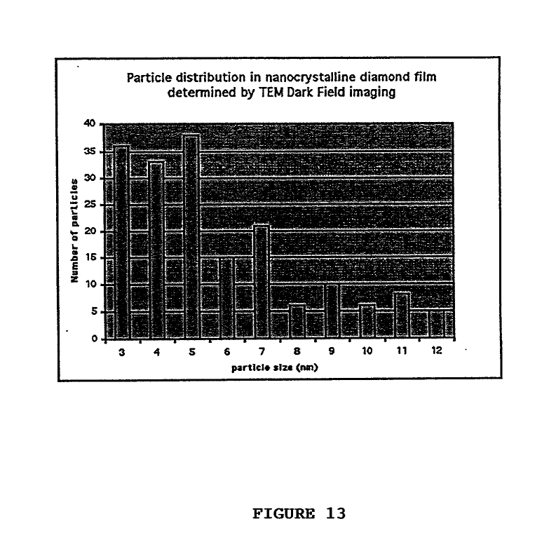

In FIGS. 12-13, the bright spots represent those grains which are aligned along the diffraction direction <111>. 2. The image was taken by selecting a fraction of the <111>ring. 3. The TEM specimen is made by a plan-view method. 4. The histogram FIG. 13 shows the grain size distribution from the D. F. image obtained with NIH imaging analysis software indicates that the grain size is predominantly of the size less and equal to 5 nm. FIG. 13 shows a histogram of particle size versus number for FIG. 12.

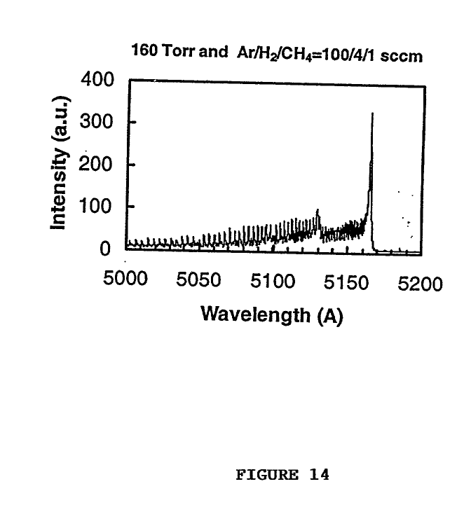

In reference to FIG. 14, the rotation temperature was measured for the d³π-a³ π(0, 0) Swan band transition of C₂.

At the pressure of 80-160 Torr the rotational temperature is expected to equal the gas temperature.

The rotation temperature Tᵣₒₜ was determined by fitting the experimental data to the expression

I˜S_{J′J″}exp[−B_{v′}J′(J′+1)/(kTᵣₒₜ)]

using the R25 to R45 emission lines (Prasad and Bernathm, Astrophy. J., vol. 426, 812 (1994); and Goyette et al., J. Phys. D.: Appl. Phys., vol. 31, 1975 (1998)).

FIG. 14 shows a typical emission spectrum. The temperature Tᵣₒₜ for this spectrum is 2650K with an uncertainty of 100K.

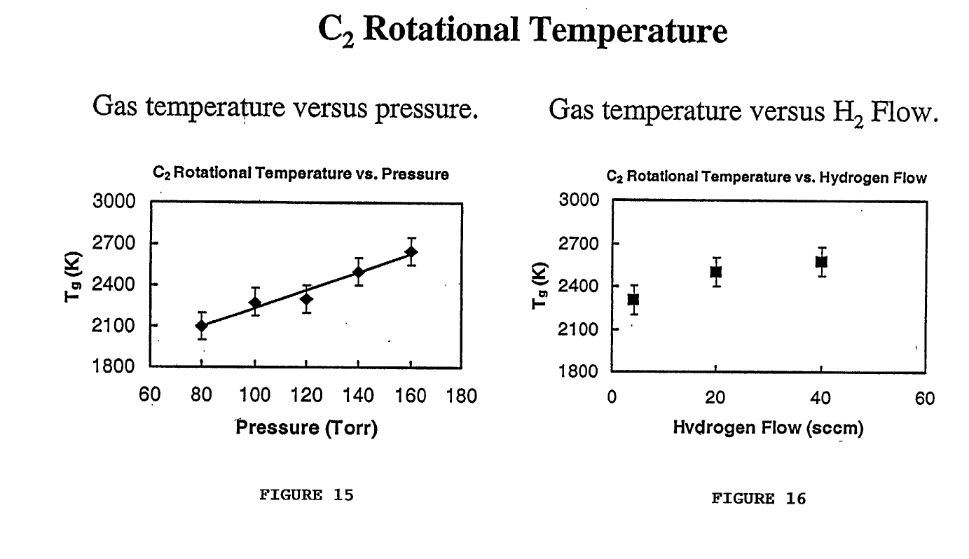

In FIG. 15, the plasma reactor settings were:

Argon flow=100 sccm

Hydrogen flow=4 sccm

Methane flow=1 sccm

In FIG. 16, the plasma reactor settings were:

Argon flow=100 sccm

Methane flow=1 sccm

Pressure=120 Torr

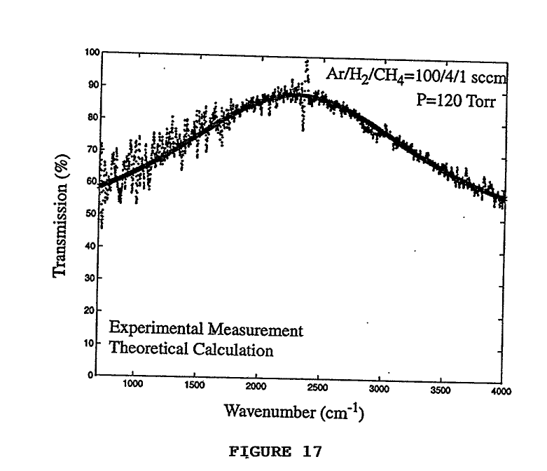

FIG. 17 shows that the measured transmission of a 3″ infrared window with a nanocrystalline diamond film on each side of Si wafer is comparable to the theoretically calculated transmission for the smooth, no-loss film. In FIG. 17 assumptions of theoretical calculation:

A planar, lossless diamond film of uniform thickness

A normally incident EM wave

Transmission is only limited by specular reflection

Surfaces of the films are smooth.

Methodology of theoretical calculation:

Matrix approach for multiple layers (I. R. Kleindienst, Master Thesis at Michigan State University (1999)

Index of refraction of diamond is calculated with Sellmeier Equation (I. R. Kleindienst, master Thesis at Michigan State University (1999).

Below:

3″ (7.62 cm) infrared window with a diamond film on each side of a silicon wafer.

The measured transmission is comparable to the theoretically calculated transmission for the ideal smooth, no-loss film.

As shown in FIG. 19, a holder 451 provided an area 251A for exposure of the surface 450A.

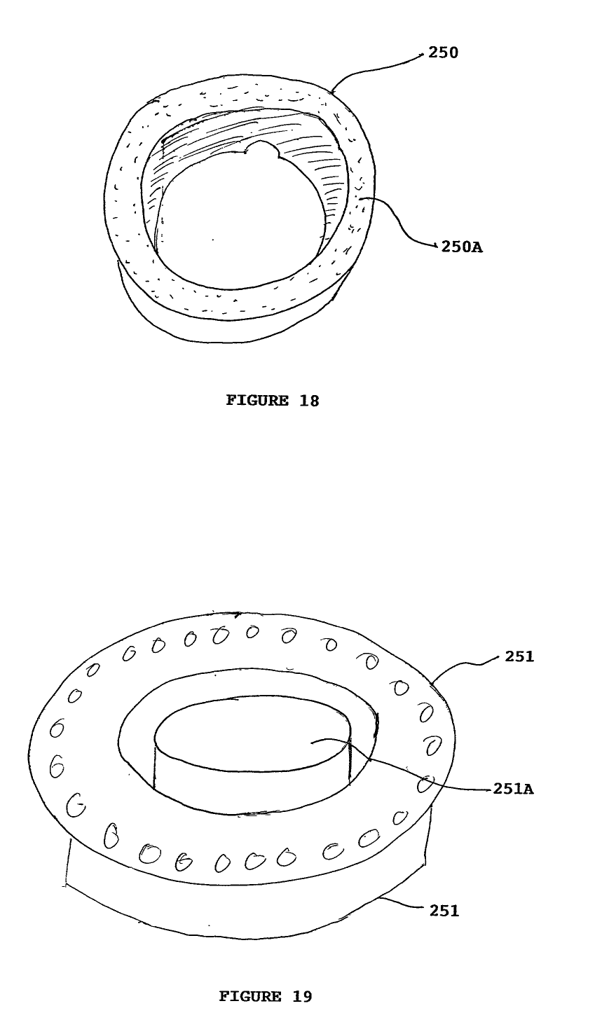

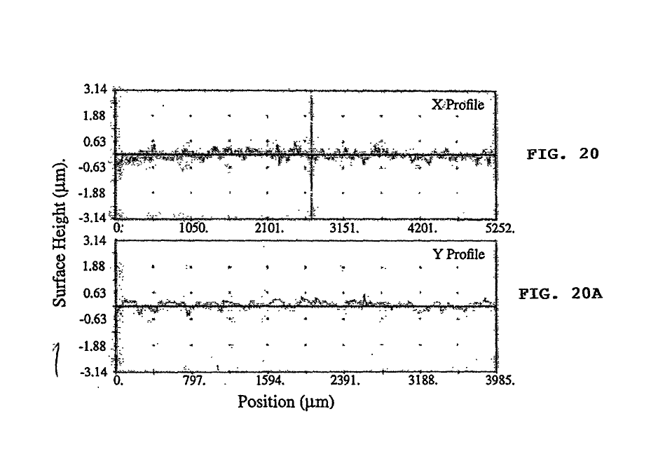

FIGS. 20 and 20A show surface profile measurement for the seal 450 surface 450A which is coated with nanocrystalline diamond shown in FIG. 18. The film had a thickness of about 3.45 microns. Raman spectroscopy characterization indicated the deposited film on the 30 μm lapped SiC seal 450 was nanocrystalline diamond. FIG. 20 shows that the measurement of the surface profile indicated the deposited film was smooth.

At a fixed operating pressure, it was observed experimentally that deposition uniformity was dependent on substrate holder geometry, substrate position, input microwave power, input gas chemistry, and total gas flow rates. Large, uniform, mostly argon discharges were created at 60-240 Torr.

Nanocrystalline diamond films were synthesized over large area 3″ (7.62 cm) diameter by using a molybdenum holder 315 as shown in FIG. 1F.

8. UV Raman Results

By varying the H₂ concentrations, the variations of the height of graphitic peaks around 1580 cm⁻¹ have been observed (FIG. 3). Lower H₂ concentrations tend to have higher graphitic peak. This usually indicates more graphite content in the nanocrystalline diamond films.

As shown by FIG. 3, by increasing the H₂ concentrations, the decreasing of the height of graphitic/amorphous carbon peaks around 1560 cm⁻¹ has been observed.

### SUMMARY

In the Examples, large, uniform, mostly argon discharges were created at 60-240 Torr. The discharges were different from usual CH₄/H₂ diamond deposition discharges. Comparatively, the gas temperatures and the power densities are lower.

At a fixed operating pressure, uniform film deposition was achieved by optimizing substrate holder geometry, substrate position, input power, input gas chemistries and total gas flow rates.

Nanocrystallinity and smooth films require high purity deposition conditions, i.e. impurities like nitrogen and/or oxygen decrease the film uniformity.

Uniform nanocrystalline films were synthesized and the crystal sizes range from 3 to 30 nm with an average about 5 nm. The film roughness (r.m.s.) Ranged from 10 to 45 nm have been achieved.

The roughness increased as H₂ concentrations and/or pressures increase.

Substrate temperatures and power absorption were independent of total gas flow rate. They depended on pressure and input gas chemistry.

The high total gas flow rates produced nonuniform films and rough surface. The preferred flow rate was 100 sccm. Preferably flow rates between 50 and 200 sccm can be used.

The growth rate was independent of the total gas flow rate. It depended on input gas chemistry, pressure, and substrate temperature.

The film growth rate increased dramatically with small increases in H₂.

The growth rates decreased as N₂ impurity increases in the range between 5-2500 ppm.

Nanocrystalline diamond films were not synthesized at pressures less than 80 Torr with substrate temperatures below 600° C.

The gas temperature for the 80-160 Torr Ar/H₂/CH₄ discharges ranged from 2100-2650 K. These temperatures were higher than those found for Ar/H₂/C₆₀ discharges by Goyette et al (J. Phys. D: Appl. Phys., vol. 31, 1975 (1998)).

Infrared transmission measurements indicate that nanocrystalline diamond films have a wide-band, low-loss transmission window. Coating irregular shaped substrates for wear resistant applications appears to be feasible.

Heating and cooling channels can be provided underneath the substrate holder 51 to adjust the process temperature of the substrate 50 to be coated. This is shown in FIG. 3 of U.S. Pat. No. 5,311,103.

It is intended that the foregoing description be only illustrative of the present invention and that the present invention be limited only by the hereinafter appended claims.

We claim:

1. A process for depositing a nanocrystalline diamond film with a grain size between 1 and 100 nm on a surface of a substrate, which comprises:
(a) providing a plasma generating apparatus for depositing the diamond film on the substrate from the plasma including a plasma source employing a radiofrequency, including UHF or microwave, wave coupler means which is metallic and in the shape of a hollow cavity and which is excited in a TM mode of resonance and optionally including a static magnetic field around the plasma which aids in coupling radiofrequency energy at electron cyclotron resonance and aids in confining ions in the plasma in an electrically insulated chamber means in the coupler means, and wherein the chamber means has a central longitudinal axis in common with the coupler means and is mounted in closely spaced and sealed relationship to an area of the coupler means with an opening from the chamber means at one end; gas supply means for providing a gas which is ionized to form the plasma in the chamber means, wherein the radiofrequency wave applied to the coupler means creates and maintains the plasma around the central longitudinal axis in the chamber means; movable metal plate means in the cavity mounted in the coupler means perpendicular to the central longitudinal axis and movable along the central longitudinal axis towards and away from the chamber means; and a movable probe means connected to and extending inside the coupler means for coupling the radiofrequency waves to the coupler means;
(b) providing the substrate, wherein the surface to be placed in the plasma has been roughened and cleaned; and
(c) providing the substrate in the insulated chamber on a substrate holder adjacent to the plasma generated in the chamber, wherein the gas in the chamber is at a pressure between 50 and 300 Torr in the presence of the radiofrequency waves for generating the plasma, wherein the gas is ninety percent by volume or more of argon along with methane and optionally hydrogen and essentially without oxygen or nitrogen and wherein the chamber is essentially free from leaks of nitrogen or oxygen or mixtures thereof into the chamber, so as to generate the plasma and to deposit the nanocrystalline diamond film on the substrate.

2. The process of claim 1 wherein the substrate has a dimension with a surface area greater than about 20 cm².

3. The process of claim 1 or 2 wherein the microwave is at 2.45 GHz.

4. The process of claim 1 or 2 wherein the microwave is at 915 MHz.

5. The process of claim 1 or 2 wherein the film has a thickness of at least about 50 nm micrometers.

6. A nanocrystalline film prepared by the process of claim 1.

7. A nanocrystalline film prepared by the process of claim 2.

8. The process of claim 1 wherein the substrate is allowed to thermally float at a temperature between about 575° C. and 900° C. on a side exposed to the plasma.

9. The process of claim 1 wherein diamond particles are used for providing the roughened surface by abrasion and wherein the diamond particles have a grain size between about 0.1 to several micrometers, which surface is then cleaned.

10. The process of claim 1 wherein the pressure on the gas is between about 60 and 240 Torr and at a flow rate of between about 50 and 200 sccm.

11. The process of claims 1 or 2 wherein the probe means is elongate and is mounted in the coupler means along the central longitudinal axis of the chamber means and coupler means with an end of the probe means in spaced relationship to the chamber means; and wherein stage means in the opening of the chamber which forms part of the cavity and provides for mounting the substrate, the stage means having a support surface which is in a plane around the longitudinal axis and which is pre-adjusted towards and away from the plasma in the chamber means so that the substrate can be coated with the diamond film from the plasma.

12. The process of claims 1 or 2 wherein the insulated chamber is evacuated so that there is less than about 10 ppm of combined oxygen and nitrogen or nitrogen or oxygen alone as the gas which generates the plasma is provided in the chamber.

13. The process of claims 1 or 2 wherein the substrate is silicon and wherein the substrate holder is molybdenum.

14. The process of any one of claims 1 or 2 wherein the substrate on which the diamond is deposited has a surface area with a diameter which is greater than about 8 cm.

15. The process of claim 1 wherein the gas contains about 1% methane.

16. The process of claim 1 wherein the mode of the plasma is selected from the group consisting of TM012 and TM013.

17. The process of claim 1 wherein at pressures of greater than about 250 Torr the stage means can be optionally cooled.

18. The process of claim 1 wherein the substrate is a silicon carbide seal and the holder is molybdenum which shields a first portion of the seal while allowing a portion of the seal to be coated with the nanocrystalline diamond.
